(19) United States
(12) Patent Application Publication
(10) Pub. No.: US 2023/0060495 A1
(43) Pub. Date: Mar. 2, 2023

(54) ADAPTABLE TEST FIXTURE FOR ELECTRICAL COMPONENTS

(71) Applicant: ARRIS Enterprises LLC, Suwanee, GA (US)

(72) Inventors: Sergio Alfredo Mendoza AGUIRRE, Escobedo (MX); Sergio Antonio Delon CANSECO, Guadalupe (MX); Carlos Paul Gonzalez INDA, Guadalupe (MX)

(73) Assignee: ARRIS Enterprises LLC, Suwanee, GA (US)

(21) Appl. No.: 17/862,112

(22) Filed: Jul. 11, 2022

Related U.S. Application Data
(60) Provisional application No. 63/236,863, filed on Aug. 25, 2021.

(51) Int. Cl. G01R 31/62; G01R 1/04

(52) U.S. Cl. CPC G01R 31/62; G01R 1/0408

(57) ABSTRACT

A fixture for testing electrical equipment. The fixture may have a tool header shaped to releasably engage the test equipment and a plunger that moves generally linearly between a first position and a second position, the first position engaging the test equipment and the second position releasing the test equipment. In some embodiments the tool is header rotatable relative to the plunger. In some embodiments, the tool header is movable relative to the plunger over at least a range of motion of the plunger.

This application claims the benefit of U.S. Provisional Patent Application Ser. No. 63/236,863 filed Aug. 25, 2021.

### BACKGROUND

This invention generally relates to the testing of electrical components, and, more specifically, to a mechanical clamp that holds passive transformers in place during testing without breaking or damaging the enclosure of the transformer.

Radio Frequency (RF) test fixtures are typically used in assemblies that either automatically or manually perform RF test measurements of electrical devices meant for PC-board mounting applications, such as passive transformers. These test fixtures couple equipment that produces the RF test signals to the devices under test (DUT). For example, a test fixture may comprise a mechanical base on which to physically install a DUT and also provide a signal path from the inputs and the outputs of the DUT to measurement equipment that provides the test signal to the inputs of the DUT and analyzes the output from the DUT. The use of a test fixture is dictated by the fact that the packages in which devices are delivered are meant for PC-board mounting applications and cannot be connected directly to test equipment connectors.

Generally, the packages in which the RF DUTs are delivered comprise a main body and electrically conductive inputs and outputs. In existing test fixtures, the DUTs are positioned and retained in place through a variety of methods (soldering, clamping, spring loading, etc.), and can be adjusted to different packages by replacing, adding, or removing mechanical sections of the fixture for each specific application. Such DUTs often comprise transformers.

Newer transformers come in SMD packaging where the original transformer is encapsulated in a plastic container and soldered to PCB terminal pads. Since each SMD transformer needs to be tested or verified, the variability of the encapsulation height creates mechanical problems such as broken parts. In addition, terminal thickness and any soldering process used creates electrical problems on measurement variability of Insertion Loss, Return Loss, Isolation and coupling measurement.

In almost all prior art fixtures, the transitions between the fixture connectors and the device package inputs and outputs are realized by using printed copper patterns over some dielectric substrate. The reason for this is that such an arrangement permits easy adaptation of the test fixture to different RF packages just by replacing a PC-board. Also, each transition can be easily designed for the specific RF packages dimensional characteristics (input/output terminals of different sizes, placed at various heights, etc.). This approach allows for the quick and easy testing of uniform device packages, i.e., RF devices that have the same dimensions. Unfortunately, such an approach has a major draw-back; RF devices of varying dimensions cannot be easily tested using a single fixture. Packaging height variability can cause enclosures to be broken during testing.

The present invention seeks to address the problem of the prior art by providing a device testing fixture that accommodates RF packages of varying heights or dimensions.

### BRIEF DESCRIPTION OF THE SEVERAL VIEWS OF THE DRAWINGS

FIG. 1 is a side view of an adaptable transformer fixture with a tool having an articulated tool head according to an embodiment of the present invention.

FIG. 2 is a front view of the tool of FIG. 1 having an exemplary ball joint by which the tool head may be adjusted to secure a DUT to the adaptable transformer fixture.

FIG. 3 is a detailed view of a test component undergoing testing being pressed against contact domes during testing as according to an embodiment of the present invention.

FIG. 4 is a view of a test base of an adaptable transformer fixture as according to an embodiment of the present invention; and

FIG. 5 is a detailed view of contact domes on a test base of an adaptable transformer fixture as according to an embodiment of the present invention.

### DETAILED DESCRIPTION

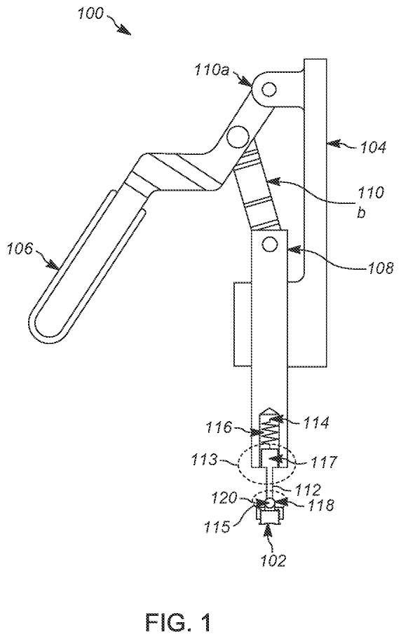

Referring to FIG. 1, an adaptable transformer fixture (100) may be used to test RF equipment (102) such as a transformer, referred to in this specification as a device under test (DUT). Though this specification will use a transformer or transformer package to illustrate the usefulness of the disclosed systems and methods, those of ordinary skill in the art will appreciate that the test fixtures and techniques disclosed in the present specification may be used with other types of electrical components (DUTs).

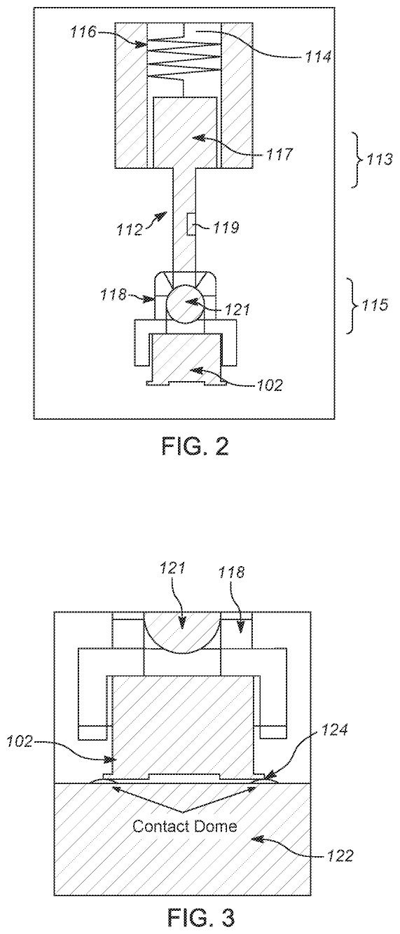

The transformer fixture (100) is designed to apply pressure to DUT (102) so that it is held firmly in place while testing occurs. In an embodiment of the present invention, the transformer fixture generally comprises a handle (106) that is connected to a fixture base (104) by way of a hinged connection (110a) and (110b). The hinged connection (110a) and (110b) allows the handle (106) to be pivotally operated by a user. The pivoting motion of the handle (106) operates a plunger section (108) slidably received in fixture base (104). At the distal end of the plunger section (108) is a chamber (114) that receives a head portion (117) of a tool (112) intended to grasp or secure the DUT (102). The tool (112) will be described in more detail with respect to FIG. 2.

During use, the plunger section (108) moves in a direction roughly parallel to the direction of the handle (102) towards or away from the DUT 102, and if moved downward while contacting the DUT (102) while supported on a platen or other surface, transfers force to the DUT (102) thereby creating a clamping force that holds the DUT (102) in place. When the user moves the handle (106) upward, or away from the DUT (102) being tested, the plunger (108) also moves away from the DUT (102), lessening the clamping force and/or releasing the DUT (102) from the transformer fixture (100).

Referring specifically to FIG. 2, the tool 112 may have a first connection (113) connecting the tool 112 to the plunger (108) and a second connection (115) connecting the tool 112 to the DUT (102). The tool (112) may structurally comprise a block portion (117) that fits snugly but slidably within the chamber (114) of the plunger (108) against a compression spring 116. The block portion (117) may be connected to a neck portion (119) that terminates at a ball joint (121) for a tool header (118) of the tool (112). The tool header (118) may be formed to engage securely around the DUT 102 and may also preferably be constructed of a nonconductive material in order to minimize interference during testing of the DUT (102).

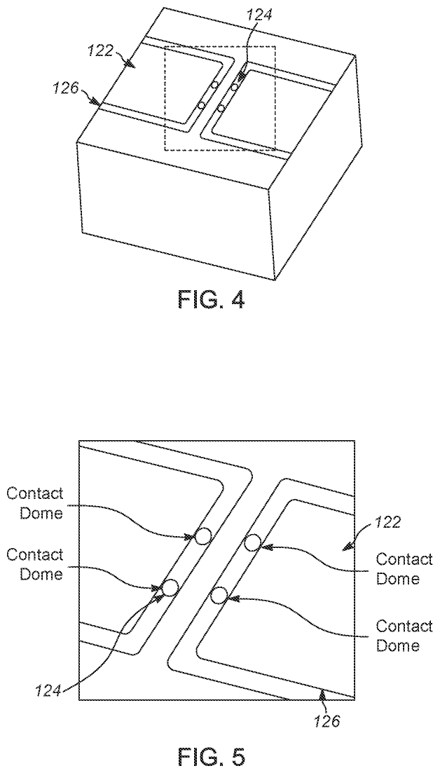

The disclosed transformer fixture (100) and its tool (112) has a number of desirable, novel features. First, the articulated ball joint 115 allows the tool header (118) to rotate freely to a position that fits the DUT (102) regardless of the angular orientation of the DUT (102), which may be supported on an uneven surface, for example. In other words, a range of motion is provided to the tool header (118) by the articulated ball joint (121) so that the header can rotate and allow for the proper positioning of the RF equipment (102) being tested. The rotational property of the tool header (118), for example, allows the DUT being tested (102) to have the correct planar angle when contacting the conductive pads that are illustrated in FIGS. 3-5.

Second, the spring (116) also allows for some of the force against the DUT (102) to be dissipated or absorbed and not transferred to the DUT (102) during testing. The spring (116) counteract the packaging height variability, eliminating the broken DUT events. The spring (116) may be contained within the plunger (108) in a chamber (114) such that the spring (116) has ample space to compress and decompress during use. When testing occurs, the plunger (108) moves toward the DUT (102) being tested. The tool header (118) is brought into contact with the DUT (102) and allows for the DUT (102) to rotate around the articulated ball joint (121) so that the DUT (102) is properly aligned to minimize electrical performance deviations. Although the spring (116) is continuously applying pressure to the DUT (102), it can compress in the spring chamber to absorb some of that downward pressure.

Those of ordinary skill in the art will realized that modifications of the physical construction of the transformer fixture can easily be made without departing from the teachings of the present disclosure. For example, rather than having a tool 112 that fits within a chamber 14 of the plunger 108, a reverse construction can be fabricated where the tool 112 fits around a terminal portion of the plunger 108, and a compression spring 116 also surrounds the plunger 108.

It should be noted that there is a space tolerance within the tool header (118) such that the tool header (118) contacts the DUT (102), but also allows for it to be easily removed from the tool header (118). That is, the tool header (118) holds and stabilizes the DUT (102), but because of the tolerance does not create a tight gripping pressure on the DUT (102). Furthermore, in some embodiment, the tool header (118) may be configured so that it can be quickly and easily detached from the articulated ball joint (121) and another header attached in its place. This allows the transformer fixture 100 to adapt to different shaped or sized pieces of RF equipment (108) being tested. The shaping of the tool header (118) that provides for the quick and easy detachment from the articulated ball joint (121) can, in some embodiments of the present invention, comprise relatively low walls that surround the ball joint (121) or the tool header (118) being constructed of a material that can deform to allow for the ball joint (121) to be removed from the tool header (118) when pulled by a user.

Referring now to FIGS. 3-5 that will be discussed together, there are shown views of the tool header (118), the DUT (102), contact pads or domes, hereinafter referred to as contact domes (124), that create an electrical connection between the DUT (102) and electrical circuits defined by traces (126) contained within a testing substrate (122). During testing, the tool header (118) presses the DUT (102) down on to the contact domes (124) so that an electrical connection is made between the DUT (102) and the traces (126) on the testing substrate (110). The contact domes (124) are preferably deformable so that when the DUT (102) is pressed down, each of the contact domes (124) changes shape and deforms proportionally to the amount of pressure applied by the DUT (102). The more each dome (124) deforms, the greater its resistance to further deformation. This creates a levelling effect for the DUT (102) such that it generally tends to orient in a plane parallel to the plane of the testing substrate (122). This levelling effect normalizes the conductive properties between the RF equipment's inputs and outputs and the traces (126) on the testing substrate (110), counteracting the DUT (102) terminal height variability.

In some embodiments of the present invention, the amount of force exerted on a piece of RF equipment such as DUT (102) can affect the electrical characteristics of that device, which is observed during testing. It is therefore important to somewhat normalize the force exerted on the DUT (102). The present invention is constructed so that the spring (116) illustrated in FIG. 2 can compress in response to the deformation resistance of the contact domes (109). That is, the less each dome (124) deforms, the more the spring (116) compresses. This property of the present invention allows for relatively consistent pressures to be exerted on each device being tested. This further enhances reliability of testing data across pluralities of tested RF equipment.

The levelling of the DUT (102) created by the contact domes (124) is accommodated by the rotational properties of the tool header (118) due to the tool header (118) being attached to the articulated ball joint (121). The tool header (118) is able to rotate around the articulated ball joint (121) proportionally to the deformation resistance inherent in each contact dome (124) that the DUT (102) is contacting.

The testing substrate (122) is designed to be interchangeable so that the transformer fixture 100 can be adjusted to accommodate testing of different pieces or types of RF equipment. Furthermore, each testing substrate (122) is alterable and can contain different configurations of electrical circuits or traces (126), different amounts of contact domes (124), and different placements of contact domes (124) on the traces (126). Each testing substrate (122) can be configured to allow for different types of tests to be run the DUT (103) depending on the particular embodiment of the present invention.

Unless otherwise defined, all technical and scientific terms used herein have the same meaning as commonly understood by one of ordinary skill in the art to which this invention belongs. Although methods and materials similar to or equivalent to those described herein can be used in the practice or testing of the symmetrical measuring tool, suitable methods and materials are described above. All publications, patent applications, patents, and other references mentioned herein are incorporated by reference in their entirety to the extent allowed by applicable law and regulations. The symmetrical measuring tool may be embodied in other specific forms without departing from the spirit or essential attributes thereof, and it is therefore desired that the present embodiment be considered in all respects as illustrative and not restrictive. Any headings utilized within the description are for convenience only and have no legal or limiting effect.

We claim:

1. A fixture for testing electrical equipment, the fixture comprising a tool header shaped to releasably engage the test equipment and a plunger that moves generally linearly between a first position and a second position, the first position engaging the test equipment and the second position releasing the test equipment, the tool header rotatable relative to the plunger.

2. The fixture of claim 1 where the tool header comprises a ball joint.

3. The fixture of claim 1 where the tool header is made of nonconductive material.

4. The fixture of claim 1 including a handle that operates the plunger.

5. The fixture of claim 4 where the handle is connected to the plunger by at least one pivoting connection.

6. The fixture of claim 1 including a spring that resists movement of the tool header towards the plunger over at least a portion of the movement of the plunger.

7. The fixture of claim 1 where the spring is positioned in a chamber in the plunger.

8. The fixture of claim 1 where the tool header is releasably engaged with a ball joint.

9. A fixture for testing electrical equipment, the transformer fixture comprising a tool header shaped to releasably engage the test equipment and a plunger that moves linearly between a first position and a second position, the first position engaging the test equipment and the second position releasing the test equipment, the tool header movable relative to the plunger over at least a range of motion of the plunger.

10. The fixture of claim 9 where movement of the tool header in a direction towards the plunger is resisted by a variable force.

11. The fixture of claim 10 where the variable force is provided by a spring.

12. The fixture of claim 1 where the tool header comprises a ball joint.

13. The fixture of claim 9 where the tool header is made of nonconductive material.

14. The fixture of claim 9 including a handle that operates the plunger.

15. The fixture of claim 14 where the handle is connected to the plunger by at least one pivoting connection.

16. An assembly comprising:
a substrate having at least one electrical trace and plurality of deformable conductive contact domes on said at least one electrical trace; and
a fixture having adapted to press a device under test (DUT) against the substrate with a force capable of deforming the contact domes; and
a member configured to level the device under test relative to the contact domes as the contact domes deform.

17. The assembly of claim 18 where the member comprises a spring.

18. The assembly of claim 18 where the member comprises a ball joint.

19. The assembly of claim 18 where the electrical traces are configured to transfer electrical impulses to and from the DUT.

20. The assembly of claim 18 where the member is configured to level the device under test relative to the contact domes as the contact domes deform by a different amount relative to each other.
